(19) United States
(12) Patent Application Publication
(10) Pub. No.: US 2011/0156012 A1
(43) Pub. Date: Jun. 30, 2011

(54) DOUBLE LAYER HARDMASK FOR ORGANIC DEVICES

(75) Inventors: Rene WIRTZ, Stuttgart (DE); Silvia Rosselli, Mannheim (DE); Gabriele Nelles, Stuttgart (DE)

(73) Assignee: SONY CORPORATION, Tokyo (JP)

(21) Appl. No.: 12/907,455

(22) Filed: Oct. 19, 2010

(30) Foreign Application Priority Data
Nov. 12, 2009 (EP) 09175840.9

(51) Int. Cl. H01L 51/05; H01L 51/40

(52) U.S. Cl. 257/40; 438/99; 257/E51.002

(57) ABSTRACT

Method of manufacturing a substrate comprising an active organic layer, the method comprising providing a substrate comprising a first layer of an organic material, depositing a second layer on the first layer of organic material, depositing a third layer on the second layer, wherein the second layer protects the first layer of organic material during the deposition of the third layer, and patterning the second layer and the third layer to form a hardmask.

### CROSS-REFERENCE TO RELATED APPLICATIONS

The present application claims priority to European patent application EP 09175840.9, filed on Nov. 12, 2009.

### FIELD OF THE INVENTION

The invention relates to a method of manufacturing a substrate comprising an active organic layer and a corresponding device comprising an active organic layer.

### DISCUSSION OF THE BACKGROUND

Organic devices are becoming increasingly important. Organic devices are frequently fabricated based on semiconductor substrates and may comprise a functional active organic layer. Preferably, these devices are processed by well established semiconductor processing methods such as standard lithography. In lithographical processes samples are treated with chemical substances such as photoresists, etchants, and solvents. In other processes the samples are exposed to deposition processes such as CVD or sputtering. Furthermore, it is a common technique to deposit hardmasks for subsequent lithographical processes. The techniques and the substances used in these processes can be harmful to organic materials that were deposited on the substrate in previous processing steps.

Regarding the protection of organic material in a semiconductor device, JP 2008 108 652 A describes a protection layer preventing an intrusion of water or oxygen from the outside. The layer is arranged over an organic element formed on a substrate and including a first electrode, an organic compound and a second electrode. The protection layer is provided with a first protection film formed by a plasma CVD method and a highly adhesive high-density second protection film formed on the first protection film by a sputtering method. However, the double dielectric layer disclosed in this document protects the whole organic device including the electrons against detrimental effects from outside. However, no protection of the organic compound is provided during the fabrication of the device after the organic compound is formed on the substrate.

U.S. Pat. No. 6,660,645 B1 discloses a process for forming a semiconductor device which includes a forming of an organic dielectric layer on a substrate, forming a protective layer on the organic dielectric layer, forming a photoresist mask on the protective layer and silyating the photoresist mask. The document does not refer to a fabrication of a hardmask.

### SUMMARY OF THE INVENTION

The problem solved by the present invention consists in providing an improved method of manufacturing a substrate comprising an active organic layer which permits to reduce harmful effects caused by subsequent processing steps of the substrate and in particular during the preparation of a hardmask, and a corresponding device comprising an active organic layer.

The problem is solved by a method of manufacturing a substrate comprising an active organic layer, wherein the method comprises providing a substrate comprising a first layer of an organic material; depositing a second layer on the first layer of organic material; depositing a third layer on the second layer, wherein the second layer protects the first layer of organic material during the deposition of the third layer, and patterning the second layer and the third layer to form a hardmask.

According to the invention, a double layer structure is deposited on a organic material layer, wherein a lower layer of the double layer structure forming a protective layer for the organic material layer protects the organic material against effects caused during the deposition of the upper layer of the double layer structure. In addition a diffusion of material of the organic layer into surrounding layers can be reduced or prevented by the protective layer. Preferably, the upper layer and the lower layer of the double layer are layers of a dielectric material.

### DETAILED DESCRIPTION OF THE INVENTION

According to one embodiment of the invention the depositing of the protective second layer is performed with a deposition process without using a plasma. Such a deposition process can be for example an evaporation or an electrochemical deposition process. Hence, during the deposition of the protective second layer the direct impact of a plasma on the organic material is avoided. Furthermore, the protective second layer protects the organic material against a potentially harmful plasma used for the deposition of further material layers.

According to another embodiment the depositing of the third layer is performed with a plasma deposition process. Since the organic material layer is protected by the protective layer the deposition of the third layer can be carried out by a plasma deposition process permitting to deposit a material that is suitable for a use as a hardmask. A plasma deposition process such as sputtering or PECVD has shown good characteristics for depositing semiconductor hard mask materials such as Si₃N₄ or oxynitrides (e.g. SiOₓN_{y}).

According to a further embodiment the method includes depositing electrodes for the first layer of organic material using the patterned second layer and the third layer as a mask. Accordingly, the second and the third layer form a double layer hard mask wherein the second layer protects the organic material layer during the deposition of the third layer. The third layer, in turn, protects the organic layer against negative effects of substances such as etchants and solvents and of the photoresist material used during the patterning of the mask.

According to yet another embodiment the patterning of the second layer and of the third layer includes etching the second layer and the third layer, wherein the second layer and the third layer have different etch rates. For example, the third layer of the double layer can have a higher etch rate than the second layer of the double layer so that the lower layer can serve as an etch stop layer. Further, it may be preferred that the second layer has a higher etch rate than the first layer comprising the organic material on which it is provided so that the etching can be stopped at the first layer. Since two materials are used for the hardmask the possibilities of material combinations and hence the possibilities of adjustment of the etch characteristics of the hardmask are increased. Suitable etch processes include chemical wet etching as well as plasma etching methods.

According to still another embodiment the method further includes depositing a dielectric layer between the substrate and the first layer of organic material. The dielectric layer can serve as a mask and can be patterned to comprise voids in which bottom electrodes for the organic layer can be provided. Furthermore, the dielectric layer can prevent a diffusion of material of the first organic layer into the surrounding material layers and in particular into the layers underneath the organic layer.

According to a further embodiment the method includes patterning the dielectric layer and forming electrodes for the first layer of organic material using the patterned dielectric layer as a mask.

According to the invention an organic device comprising an active organic layer is provided. The device includes a substrate, a first layer of organic material formed on the substrate, a protective second layer deposited on a first layer of organic material and a third layer deposited on the second layer, wherein the second layer and the third layer of organic material are patterned as a hardmask for a further processing of the device.

The protective second layer that is deposited on the layer of organic material reduces or prevents the impact that further processing steps of the device including a deposition of a further layer and in particular a deposition involving a plasma deposition process such as sputtering or PECVD may have on the organic first layer. In addition, a diffusion of substances from the organic layer into adjacent material layers can be prevented. Due to the provision of the protective second layer techniques for the deposition of the third layer can be used that are potentially more aggressive with respect to the organic material layer but which in turn permit a deposition of materials that are well suited as materials for a hardmask.

In addition, the third layer may provide an inertness of the organic material against a diffusion of chemicals used during a lithographic process.

According to one embodiment the second layer deposited on the layer of organic material consists of a material that is deposited with a deposition process without using a plasma. Such a process can be for example an evaporation process or a electrochemical deposition technique or a coating process. Hence, a detrimental influence of a potentially detrimental deposition method such as a plasma deposition technique on the layer of organic material can be prevented.

According to another embodiment the material of the second layer is a dielectric material such as SiO and SiO₂ and other oxides (e.g. Gd₂O₃, Y₂O₃, Al₂O₃, BaSrTiO₃, BaTiO₃) or fluorides (CaF₂, LiF) without being restricted thereto. These materials can be deposited for example by an evaporation process that is less harmful for the organic material.

According to another embodiment the third layer deposited on the organic material consists of a material that can be deposited with a plasma deposition process. A plasma deposition process such as a sputtering process or PECVD permits a deposition of materials that are suitable for a hard mask for subsequent lithographic processing.

According to another embodiment the material of the third layer is a dielectric material such as a silicon oxynitride and in particular Si₃N₄.

According to a further embodiment the material of the second layer and the material of the third layer have different etch rates. In addition they may be sensitive to different etch agents. Due to the different etch rates and etch agents one of the layers of the double layer mask, preferably the layer provided directly on the organic material layer may serve as a stop etch layer. Furthermore, one of the second and the third layer or both may have a different etch rate and etch agents than the organic layer. Then the second layer can be selectively etched, while the etching stops at the organic layer.

According to another embodiment the device comprises a dielectric layer between the substrate and the first layer of organic material, wherein the dielectric layer is patterned as a mask. This mask may be used for a deposition of bottom electrodes to the active organic layer. In addition the dielectric layer can act as a diffusion barrier for material of the active organic layer into surrounding layers.

According to an embodiment the substrate comprises a semiconductor stack that can generally comprise multiple strained or unstrained layers of a semiconductor, dielectric or metallic material or combinations thereof that can function as transistors, diodes, capacitors or can have any other electronic functionality.

According to a further embodiment the active organic layer can be one of an organic semiconductor, a semiconductor p-n junction, a resistively switching material, or a conductive polymer or can be a combination thereof and has a corresponding functionality. The active organic layer can also include several layers.

According to another embodiment the active organic layer consists of a molecular layer or of a metal-insulator-metal (MIM) junction and forms a resistive switch that exhibits resistive switching. The resistive switch may be formed by a metal-polymer-metal system wherein the polymer comprises semiconductive characteristics. Furthermore, the material may show the so called “filament switch effect”.

According to a further embodiment organic semiconductor materials for a use in the MIM system can be polymers of the group including poly(acetylene)s, poly(pyrrole)s, poly(3-alkylthiophenes)s, polyanilines, polythiophenes, poly(p-phenylene sulfide), and poly(para-phenylene vinylene)s (PPV), polyindole, polypyrene, polycarbazole, polyazulene, polyazepine, poly(fluorene)s, and polynaphthalene without being restricted thereto. P-type organic semiconductors are for example molecules like pentacene, tetraceno[2,3-b]thiophene, TIPS-pentacene, α-sexithiophene, oligothiophene-fluorene derivative, Bis(ethylenedithio)tetrathiafulvalene, (BEDT-TTF), Bis(4,5-dihydronaphtho[1,2-d])tetrathiafulvalene, Copper (II) phthalocyanine, Platinum octaethylporphyrin only to citate a few without being restricted thereto. n-type organic semiconductor are molecules like Fullerene-C60, Fullerene-C70, Fullerene-C84, Hexadecafluoro copper phthalocyanine, Pd(II) meso-Tetra(pentafluorophenyl)porphine, 1,4,5,8-Naphthalenetetracarboxylic dianhydride, Perylene-3,4,9,10-tetracarboxylic dianhydride, N,N′-Dipentyl-3,4,9,10-perylenedicarboximide, N,N′-Dioctyl-3,4,9,10-perylenedicarboximide (PTCDI-C8), N,N′-Diphenyl-3,4,9,10-perylenedicarboximide (PDCDI-Ph), 7,7,8,8-tetracyanoquinodimethane (TCNQ), 2,3,5,6-Tetrafluoro-7,7,8,8-tetracyanoquinodimethane (F4TCNQ) without being restricted thereto.

According to yet another embodiment a further group of suitable polymers includes for example poly(3-hexylthiophene) (P3HT), polyaniline, poly(phenylene vinylene)-disperse red 1 (PPV-DR1), polysiloxane carbazole (PSX-Cz), polypyrrole, poly(o-anthranilic acid) (PARA) and poly(aniline-co-o-anthranilic acid) (PANI-PARA). The polymer is contacted by at least one metal having a high ion mobility like Cu, Au, Ag etc.

The structural formulas of the above mentioned polymers are shown below:

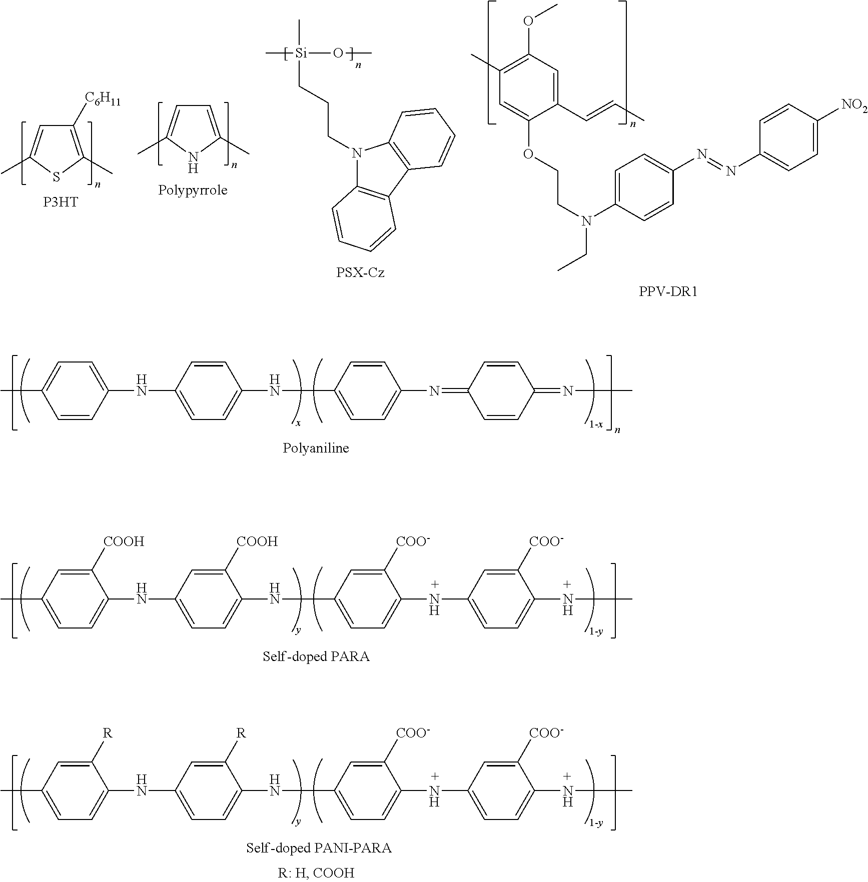

According to another embodiment suitable materials for the active organic layer can also include or consist of materials that exhibit a change of conductivity upon application of an electrical field such as a resistively switching material. Resistively switching materials can be materials that include components that undergo a charge transfer in response to an application of an electric field. This category of materials also includes resistively switching materials that undergo a charge transfer with a connected electrode in response to an application of an electric field. Suitable materials for the electrode include metals like Cu, Au, Ag etc.

Generally, these materials referred to as charge-transfer complexes are electron-donor-electron-acceptor complexes that are characterized by at least one electronic transition to an excited state in which there is a partial transfer of an electronic charge from the donor to the acceptor moiety.

Donor and acceptor molecules in the charge transfer complex are so defined that the highest occupied molecule orbital (HOMO) of the donor and the lowest unoccupied molecule orbital (LUMO) of the acceptor are close enough with each other that upon application of an electric field an electron of the HOMO of the donor can transfer to the LUMO of the acceptor and vice versa depending on the electric field direction.

Donor molecules are molecules that donate electrons during the formation of the charge transfer complex.

Donor molecules can include one or more of the following donor groups without being restricted thereto: O⁻, S⁻, NR₂, NAr₂, NRH, NH₂, NHCOR, OR, OH, OCOR, SR, SH, Br, I, Cl, F, R, Ar. They can be single molecules, oligomers or polymers.

According to yet another embodiment the resistively switching material of the active organic layer comprises a donor molecule of one of the following formulas without being restricted thereto:

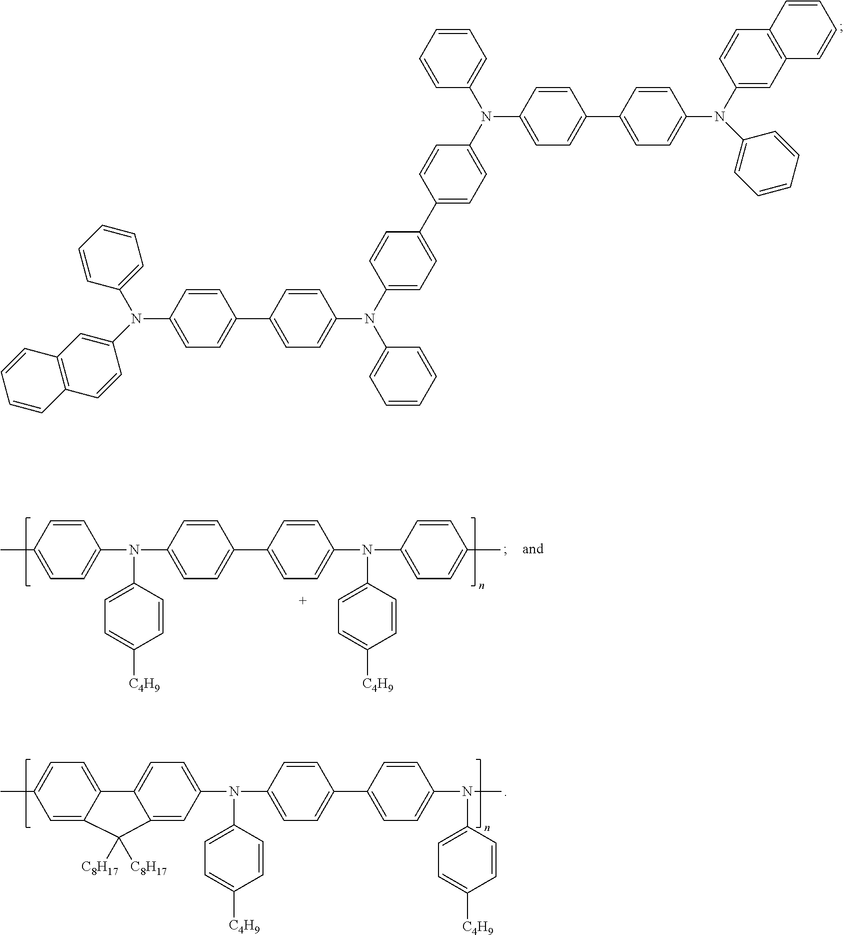

Acceptor molecules are molecules that accept electrons during the formation of a charge transfer complex.

Acceptor molecules can contain one or more of the following acceptor groups without being restricted thereto: NO₂, CN, COOH, COOR, CONH₂, CONHR, CONR₂, CHO, COR, SO₂R, SO₂OR, NO, Ar. They can be single molecules, oligomers or polymers.

Acceptor molecules are found also among the fullerene derivatives, semiconductor nanodots and electron poor transition metal complexes.

According to another embodiment the resistively switching material comprises an acceptor molecule of the group comprising C60 fullerene, C61 fullerene, CdSe, and platinum octaethyl porphine.

According to yet another embodiment the resistively switching material of the active organic layer undergoing a charge transfer in response to an application of an electric field is a material having conjugated main-chain as well as side-chain liquid crystalline polymers which can be aligned in mono-domain or multi-domain structures.

According to yet another embodiment the resistively switching material has the following formula without being restricted thereto:

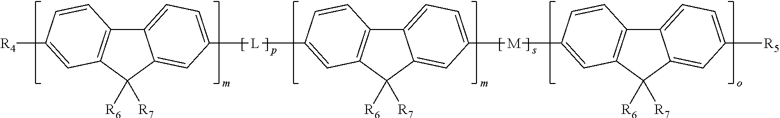

wherein R4 and R5 are independently at each occurrence selected from the group comprising:

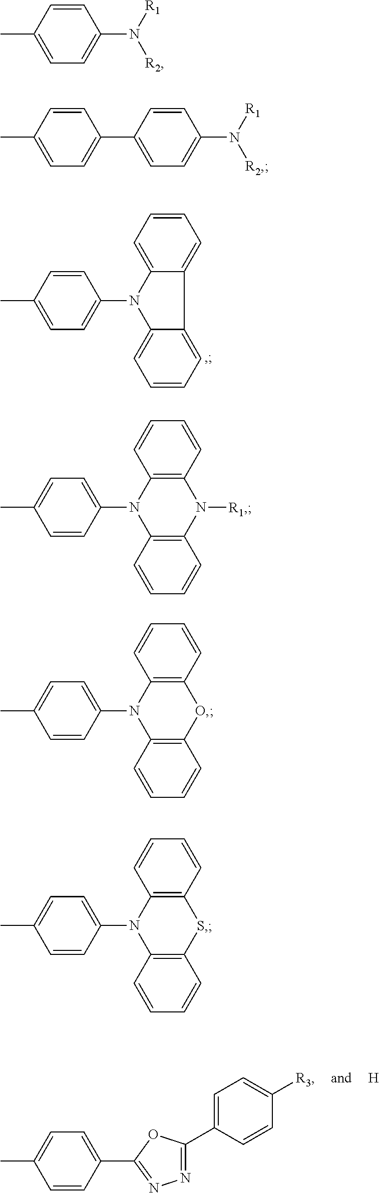

R1 and R2 being independently selected from the group comprising straight chain C₁₋₂₀ alkyl, branched C₁₋₂₀ alkyl, aryl, substituted aryl, alkylaryl, substituted alkylaryl, alkoxyaryl, substituted alkoxyaryl, aryloxyaryl, substituted aryloxyaryl, dialkylaminoaryl, substituted dialkylaminoaryl, diarylaminoaryl and substituted diarylaminoaryl,
R3 being selected from the group comprising straight chain C₁₋₂₀ alkyl, branched C₁₋₂₀ alkyl, aryl, substituted aryl, alkylaryl and substituted alkylaryl, and wherein R6 and R7 are independently at each occurrence selected from the group comprising straight chain C₁₋₂₀ alkyl, branched chain C₁₋₂₀ alkyl, aryl, substituted aryl, alkylaryl, substituted alkylaryl, —(CH₂)_{q}—(O—CH₂—CH₂)ᵣ—O—CH₃,
q being selected from the range 1<=q<=10, r being selected from the range 0<=r<=20, and wherein L and M are independently at each occurrence selected from the group comprising thiophene, substituted thiophene, phenyl, substituted phenyl, phenanthrene, substituted phenanthrene, anthracene, substituted anthracene, any aromatic monomer that can be synthesized as a dibromo-substituted monomer, benzothiadiazole, substituted benzothiadiazole, perylene and substituted perylene, and wherein m+n+o<=10, each of m, n, o being independently selected from the range 1-1,000, and wherein p is selected from the range 0-15, and wherein s is selected from the range 0-15, with the proviso that, if R4 is H, R5 is not H, and if R5 is H, R4 is not H.

According to a further embodiment the resistively switching material of the active organic layer has the following formula without being restricted thereto:

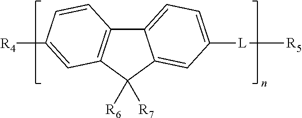

wherein L independently at each occurrence is selected from the group consisting of thiophene, substituted thiophene, phenyl, substituted phenyl, phenanthrene, substituted phenanthrene, anthracene, substituted anthracene, any aromatic monomer that can be synthesized as a dibromo-substituted monomer, benzothiadiazole, substituted benzothiadiazole, perylene and substituted perylene, and wherein R₆ and R₇ are independently at each occurrence selected from the group consisting of straight chain C₁₋₂₀, branched chain C₁₋₂₀ alkyl, aryl, substituted aryl alkylaryl, —(CH₂)_{q}—(O—CH₂_{_{—}}CH₂)ᵣ—O—CH₃, q being selected from the range 1-10, r being selected from the range 0-20 and wherein R4 and R5 are independently at each occurrence selected from the group comprising:

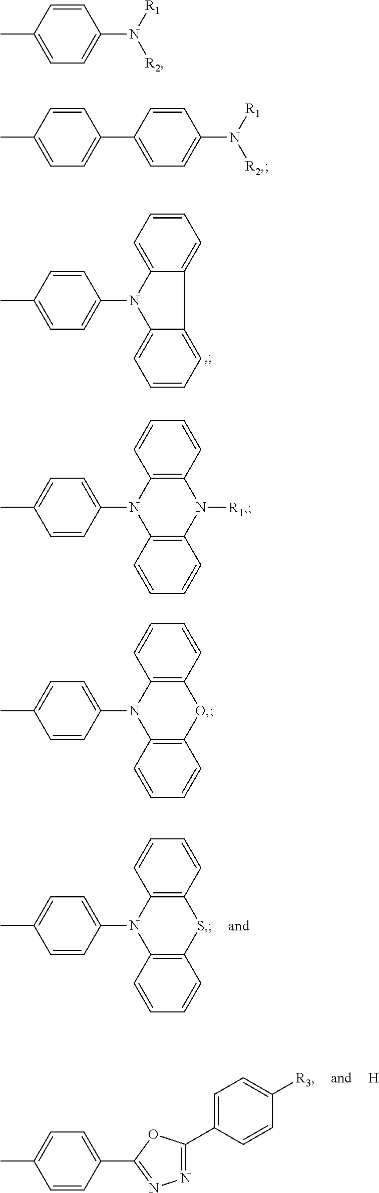

According to another embodiment the resistively switching material has one of the following formulas without being restricted thereto:

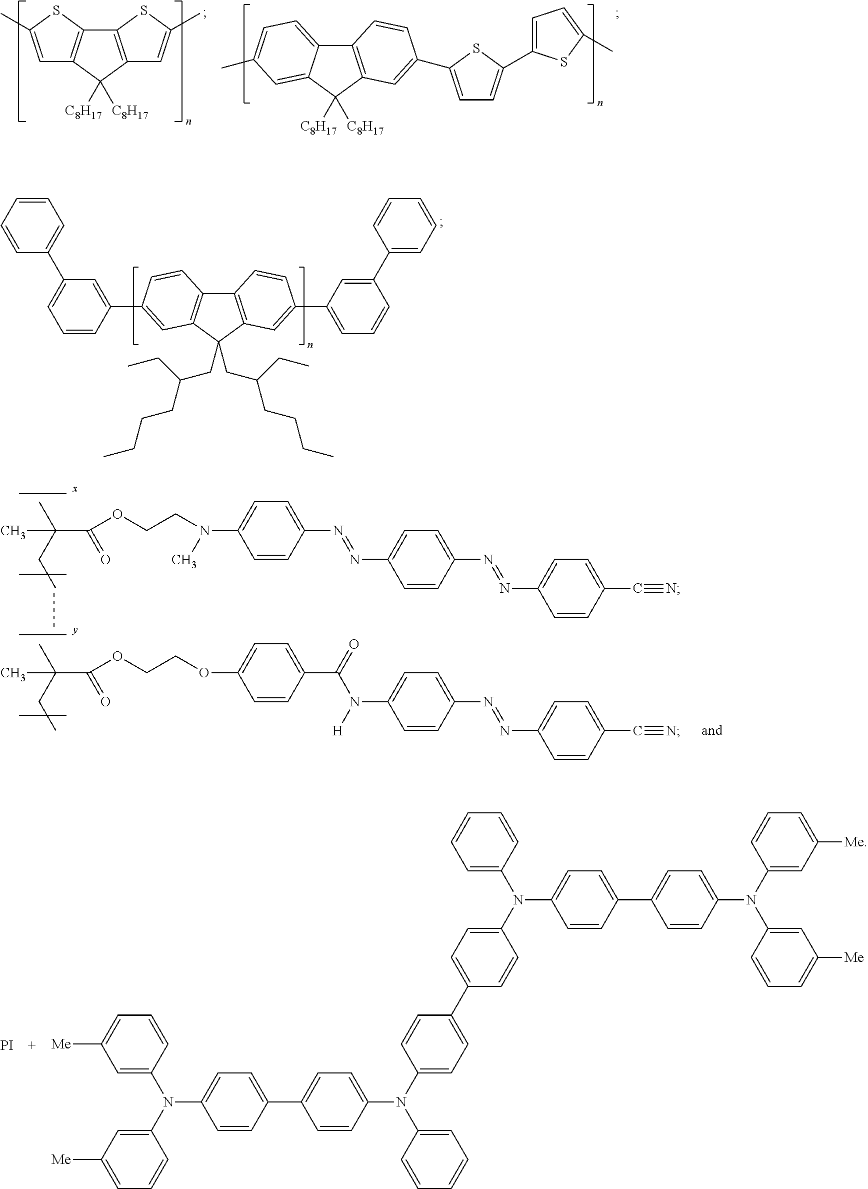

According to another embodiment the resistively switching material is an endcapped polyfluorene of the following formula without being restricted thereto:

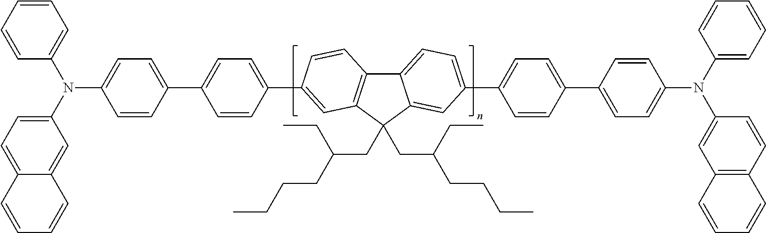

According to yet another embodiment the material is aligned on a substrate including a semiconductor stack by the use of alignment layers or by other methods such as direct mechanical rubbing, by using an electric field or magnetic field. The alignment results in dipole reorientation and a better charge transfer from the electrode or between the layer components.

For all resistively switching materials described above exhibiting a charge transfer in an electric field, the charge transfer may occur intramolecular or intermolecular to the molecules of the material. A charge transfer may also occur between a molecule and a connected electrode such as the gate electrode of a field effect transistor or contacts.

In an intramolecular charge transfer complex the donor and the acceptor moiety are part of the same molecule. The intramolecular charge transfer molecule can be a single molecule, an oligomer or polymer.

According to another embodiment the resistive switching material includes an electron poor molecule. Generally, electron poor molecules are molecules with electron withdrawing groups (with positive Hammett, δ, constant) and any electron donor groups and transition metal complexes with ligands having electron withdrawing groups directly attached to the metal. They can be single molecules, oligomers or polymers.

According to a further embodiment the electron poor molecules are defined by one of the following formulas without being restricted thereto:

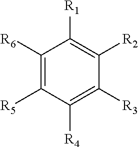

wherein R, R₁, R₂, R₃, R₄, R₅, R₆═C═O, COOH, F, Cl, Br, I, CN, NO₂, NR₃⁺, O—Ar, COOR, OR, COR, SH, SR, CONH₂, CONHR, CONR₂, CHO, OH, SO₂R, SO₂OR, NO, C≡CR, Ar; and

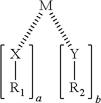

wherein M=transition metal, X, Y=electron withdrawing group like C═O, COOH, F, Cl, Br, I, CN, NO₂, NR₃⁺, N═C, O—Ar, COOR, OR, COR, SH, SR, CONH₂, CONHR, CONR₂, CHO, C═N, OH, SO₂R, SO₂OR, NO, C≡CR, Ar and R₁, R₂=aromatic, allilylic; a, b=integer number.

According to yet another embodiment the electron poor molecule comprises one of the following formulas without being restricted thereto:

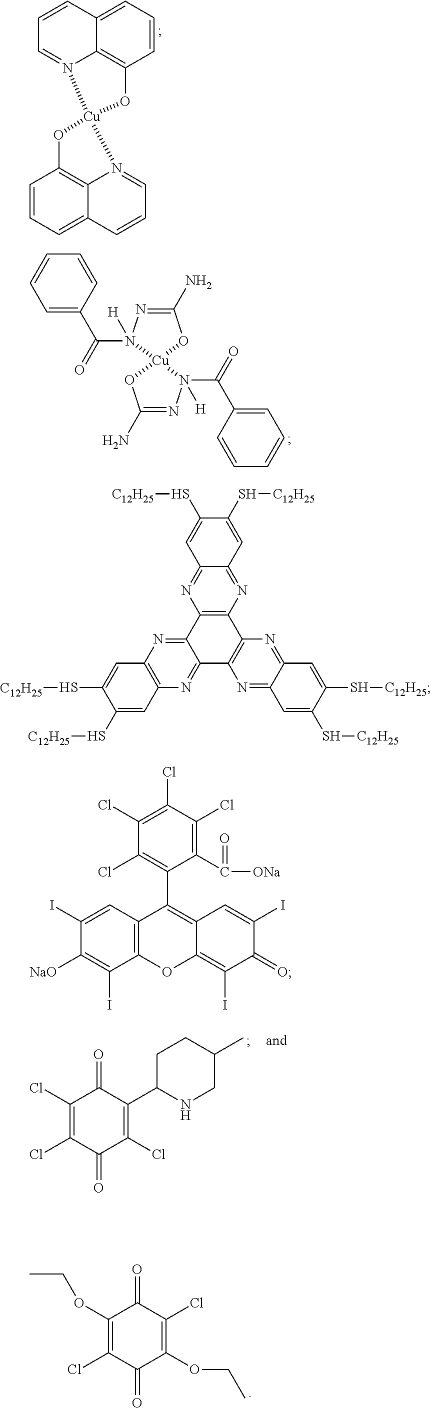

According to still a further embodiment the resistively switching material comprises a Redox-addressable molecule. Generally, redox addressable molecules are molecules in which the conjugation length and with it the conductivity changes upon chemical reduction or oxidation. They can be single molecules, oligomers or polymers. A typical redox addressable group are the 4,4′ bipyridinium salts.

According to one embodiment the Redox-addressable molecules are defined by the formula without being restricted thereto:

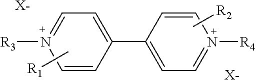

wherein R₁, R₂, R₃, R₄=aryl or alkyl
X⁻=anion.

According to an embodiment the Redox-addressable molecule comprises one of the formulas without being restricted thereto:

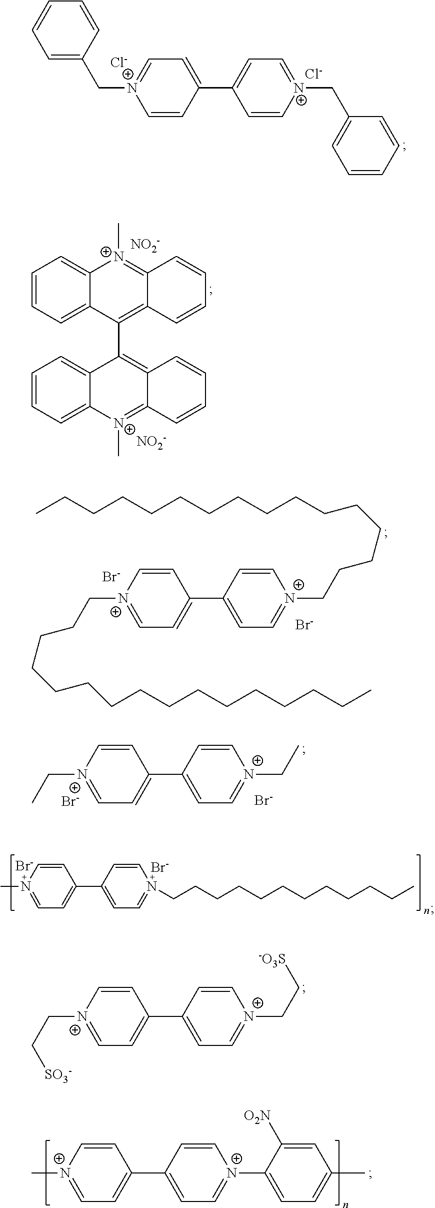

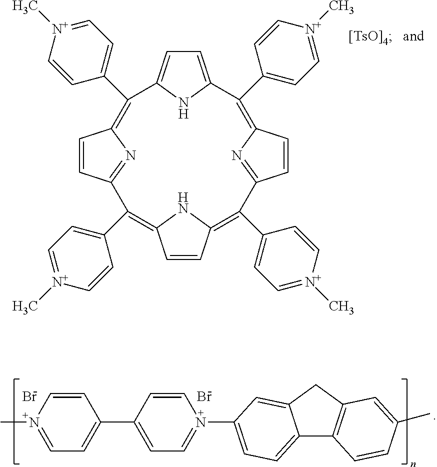

The layer of resistive switching material is usually amorphous and can easily be deposited on top of a substrate by using conventional deposition methods such as thermal evaporation, sputtering or spin-coating, by layer by layer deposition, electrostatic self-assembly and Langmuir Blodgett technique etc.

According to another embodiment a specific example of a material comprising electron poor molecules are active films of hexaazatrinaphthylene (HATNA) prepared by spin coating of a chloroform solution. The films can be dried under vacuum conditions. Then Aluminium electrodes may be deposited thought a mask (0.25 mm²) to form a complete switch.

Under application of a voltage profile an ON-OFF ratio of 2.3 within 20 cycles could be measured in an experimental setup.

In a redox addressable molecule the injection of electrons by an electric current chemically reduces the molecule and the increased amount of electrons in the π*orbitals increases the conductivity of the material which is transferred from a low conduction state (OFF) to a high conduction state (ON).

According to still another embodiment a resistively switching material includes a layer of Redox-addressable octadecyl viologen dibromide prepared for example by the Langmuir Blodgett technique, a layer of Redox-addressable poly(viologen-co-dodecane) prepared by spin coating of a chloroform/ethanol solution; and a layer of Redox-addressable 1,1′-diethyl-4,4′ bipyridinium dibromide prepared by evaporation. Of course these materials can also be prepared with a technique that was indicated in relation with another material.

Further details with respect to materials that can be used as a resistively switching material and their preparation are disclosed in the European patent application EP 07 01 57 11 that is hereby incorporated by reference.

As the main characteristic a resistively switching material layer comprises two stable states which differ in the resistance of the layer: A low resistive (“ON”) state and a high resistive (“OFF”) state. By applying a positive or a negative voltage pulse, it is possible to switch between these states. The state of the switching material layer is stored even if no voltage is applied to the switching material layer.

In the case of a charge transfer complex material the process of a conductivity change between the components of the charge transfer complex upon application of an electric field can be explained as follows on a molecular scale: In a low-conductivity state, which can be considered as the “off” state, charge carriers such as electrons occupy the lowest energy levels. Due to an application of an electric field such as a voltage pulse electrons are transferred from a donor molecule to an acceptor molecule. As a result, charge carriers occupy higher energy levels. Thus the material is in a state of high conductivity or “on” state.

According to another embodiment a conductive polymer is a polymer of the group including poly(3,4-ethylenedioxythiophene) poly(styrenesulfonate) PEDOT:PSS, doped polyanilines without being restricted thereto.

The device may include additional layers not described so far. In particular, one or several material layers may be provided between the substrate and the dielectric layer, between the substrate and the first layer of organic material, between the dielectric layer and the first layer of organic material, or between the first layer of organic material and the protective second layer.

### BRIEF DESCRIPTION OF THE FIGURES

Further advantages, features and characteristics of the invention may result from the following description of an exemplifying embodiment of the present invention in connection with the accompanying drawing.

FIG. 1 shows a cross-sectional view of a scheme of a device comprising an active organic layer according to one embodiment of the invention.

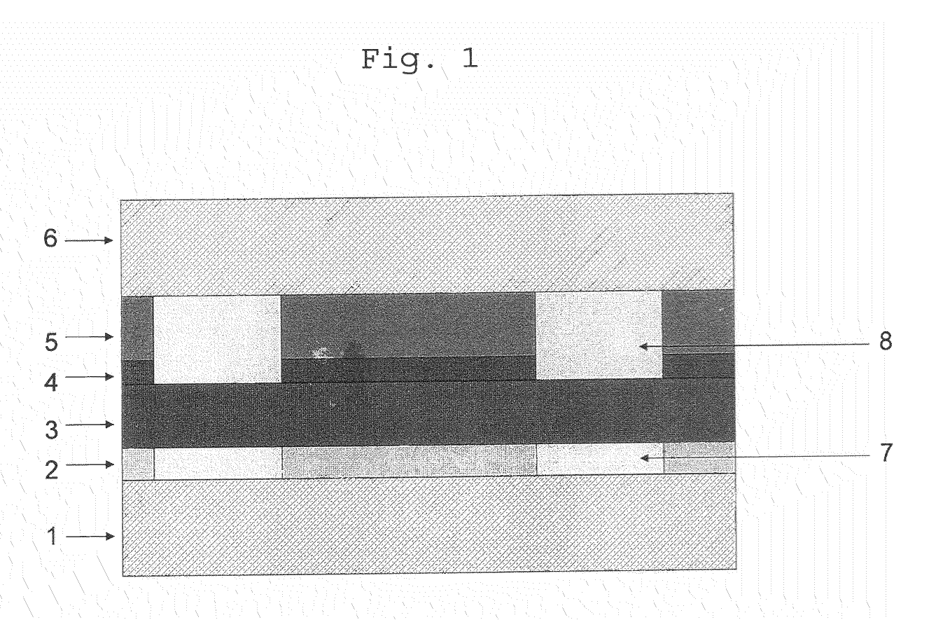

The device comprising an active organic layer shown in FIG. 1 includes a substrate 1 such as a semiconductor stack which is capped with a single dielectric layer 2 acting as a diffusion barrier and as a hard mask for lithography. The semiconductor stack can generally comprise multiple strained or unstrained layers of a semiconductor, dielectric or metallic material or combinations thereof that can function as transistors, diodes, capacitors or can have any other electronic functionality. The single dielectric layer 2 is patterned to comprise voids in which electrodes 7 are deposited. The electrodes 7 contact a layer of an organic material 3 provided on top of the single dielectric layer 2 and provide electric contacts to the organic layer 3. The organic layer 3 is a functionally active organic layer as described above.

The organic layer 3 is covered by a double layer including a layer 4 that serves as a protective layer and layer 5 that is deposited on top of the protective layer 4 and is formed of a material that is suitable as a hard mask material such as silicon oxynitrides, in particular Si₃N₄.

The lower layer 4 of the double layer is deposited on the organic layer 3 with a deposition process without using a plasma such as an evaporation process. Hence, a detrimental impact on the organic layer 3 of a plasma can be avoided. Furthermore, the lower layer 4 of the double layer acts as diffusion barrier preventing a diffusion of materials of the organic layer 3 to surrounding layers. A material that is suitable as a protective layer for a subsequent plasma deposition process is SiO or SiO₂ evaporated on the organic material layer. Other oxide layers can be suited as well. The thickness of the layer of SiO or SiO₂ is preferably in the range between a few nanometers and several micrometers.

In contrast, the upper layer 5 of the double layer is deposited with a plasma deposition process such as sputter deposition, ion plating or plasma assisted chemical vapour deposition. Due to the protection of the organic layer 3 by layer 4, a detrimental effect that the plasma deposition process may have on the organic material of the organic layer 3 can be avoided.

The thickness of the upper layer 5 can vary between a few nanometers and several micrometers. The upper layer 5 provides a protection of the organic layer 3 against a diffusion of chemicals used during a subsequent lithographic process. A lithographic process may include the deposition of a negative or positive photoresist, the exposure of the photoresist to a radiation source to pattern the resist and subsequent removal of exposed or not-exposed photoresist with a solvent to transfer the exposure pattern to the photoresist. In addition, an etch process is performed etching parts of the double layer to transfer the pattern of photoresist to the double layer thereby forming the double layer hardmask.

The thickness of the lower layer 4 can vary between several nanometers and several micrometers, as long as the protection of the underlying organic material against the plasma necessary for the deposition of the upper layer is secured.

In the voids of the hardmask electrodes 8 are deposited that contact the active organic layer 3. The electrodes 8 can be used as electric top contacts to the organic layer 3 and can be formed of typical materials for electrodes such as without being restricted thereto Au, Ni, Pt, Cu, Al, Ag, Cr, Ti, etc. On top of the double layer further semiconductor layers such as layer 6 can be deposited.

In order to support the etching steps which are used to pattern the hardmask following the lithography materials may be selected for the layers of the double layer that have etch rates that distinguish from the etch rate of the organic layer. The top layer of the dielectric double layer can be made of a material with superior diffusion barrier properties, while having similar etch properties as the organic layer while the bottom layer of the double layer preferably has a lower etch rate and functions as a stop etch.

The features of the invention as described above can be of importance for the invention in any combination.

1. Method of manufacturing a substrate comprising an active organic layer, the method comprising:
providing a substrate (1) comprising a first layer (3) of an organic material;
depositing a second layer (4) on the first layer (3) of organic material;
depositing a third layer (5) on the second layer (4), wherein the second layer (4) protects the first layer (3) of organic material during the deposition of the third layer; and
patterning the second layer (4) and the third layer (5) to form a hardmask.

2. Method of claim 1, wherein the depositing of the second layer (4) is performed with a deposition process without using a plasma.

3. Method of claim 1 or 2, wherein the depositing of the third layer (5) is performed with a plasma deposition process.

4. Method of one of claims 1 to 3, including depositing electrodes for the first layer (3) of organic material using the patterned second layer (4) and the third layer (5) as a mask.

5. Method of claim 4, wherein patterning the second layer (4) and the third layer (5) includes etching the second layer (4) and the third layer (5), wherein the second layer (4) and the third layer (5) have different etch rates.

6. Method of one of claims 1 to 5, further including depositing a dielectric layer (2) between the substrate and the first layer (3) of organic material.

7. Method of claim 6, including patterning the dielectric layer (2) and forming electrodes for the first layer (3) of organic material using the patterned dielectric layer (2) as a mask.

8. Device comprising an active organic layer, including:
a substrate (1);
a first layer (3) of organic material formed on the substrate (1);
a second protective layer (4) deposited on the first layer (3) of organic material; and
a third layer (5) deposited on the second layer (4), wherein the second layer (4) and the third layer (3) of organic material are patterned as a mask for a further processing of the device.

9. Device of claim 8, wherein the second layer (4) deposited on the layer (3) of organic material consists of a material deposited with a deposition process without a plasma.

10. Device of claim 8 or 9, wherein the material of the second layer (4) is a dielectric material of one of SiO and SiO₂.

11. Device of one of claims 8 to 10, wherein the third layer (5) deposited on the organic material consists of a material deposited with a plasma deposition process.

12. Device of one of claims 8 to 11, wherein the material of the third layer (5) is a dielectric material of one of silicon oxynitride and Si₃N₄.

13. Device of one claims 8 to 12, wherein the material of the second layer (4) and the material of the third layer (5) have different etch rates or are sensitive to different etch agents.

14. Device of one of claims 8 to 13, comprising a dielectric layer (2) between the substrate (1) and the first layer (3) of organic material, the dielectric layer (2) patterned as a mask.

15. Device of one of claims 8 to 14, comprising one or more of a metallic, a dielectric and a semiconductor layer (6) or combinations thereof deposited on top of the third layer (5).
